(19) United States
(12) Patent Application Publication
(10) Pub. No.: US 2012/0188184 A1
(43) Pub. Date: Jul. 26, 2012

(54) DISPLAY HAVING A FRAME, TOUCH DISPLAY, AND METHOD OF MANUFACTURING A FRAME

(75) Inventors: Ming-Chuan Lin, Taichung City (TW); Hsueh-Chih Wu, Taichung City (TW); Ming-Che Chan, Taichung City (TW); Wen-Yi Wang, Taichung City (TW); Chao-Hsiang Chiang, Taichung City (TW); Chu-Yu Yeh, Taichung City (TW); Chao-Chi Liao, Taichung City (TW)

(73) Assignees: WINTEK CORPORATION, Taichung City (TW); DONGGUAN MASSTOP LIQUID CRYSTAL DISPLAY CO., LTD., Guangdong Province (CN)

(21) Appl. No.: 13/353,282

(22) Filed: Jan. 18, 2012

(30) Foreign Application Priority Data
Jan. 25, 2011 (TW) 100102731

(51) Int. Cl. G06F 3/041; B23P 17/04; H05K 7/14

(52) U.S. Cl. 345/173; 361/807; 29/592

(57) ABSTRACT

A display having a frame, a touch display, and a method of manufacturing a frame are provided. The display includes a first frame, a second frame, and a display panel. The first frame includes a bottom surface, a sidewall, and a strengthened structure. The sidewall connects the bottom surface to define an accommodation space. The strengthened structure connects a terminal of the sidewall away from the bottom surface, is located at a side of the sidewall facing the accommodation space, and is substantially parallel to the sidewall. The strengthened structure has a contact surface. The contact surface faces the bottom surface and is substantially parallel to the bottom surface. The second frame is configured in the accommodation space and has a locking portion that has a locking surface leaning against the contact surface of the strengthened structure. The display panel is accommodated in the second frame.

### CROSS-REFERENCE TO RELATED APPLICATION

This application claims the priority benefit of Taiwan application serial no. 100102731, filed on Jan. 25, 2011. The entirety of the above-mentioned patent application is hereby incorporated by reference herein and made a part of this specification.

### BACKGROUND OF THE INVENTION

1. Field of the Invention

The invention relates to a display, a touch display, and a method of manufacturing a frame. More particularly, the invention relates to a display with favorable mechanical strength, a touch display with favorable mechanical strength, and a method of manufacturing a frame.

2. Description of Related Art

A liquid crystal display (LCD) is comprised of a liquid crystal panel and a backlight module. Liquid crystal in the liquid crystal panel is not self-illuminating, and therefore the liquid crystal panel need be illuminated by the backlight module which supplies the planar light source. The backlight module often includes a light guide plate, a light source, and a plastic frame. The plastic frame holds the light guide plate and the light source, and a display panel is assembled to the plastic frame.

To secure the assembly of the plastic frame and the casing of an electronic apparatus and protect the liquid crystal panel and each component in the plastic frame, the plastic frame and the liquid crystal panel are frequently covered by a metal frame. Hence, the plastic frame and the metal frame should respectively have a locking structure, such that the plastic frame and the metal frame can be fixed together. In general, the plastic frame has a locking protrusion, and the metal frame has a hole. The locking protrusion is suitable for passing through and locking the hole, so as to assemble the plastic frame and the metal frame together.

However, the hole design weakens the strength of the metal frame, which leads to a decrease in the mechanical strength of the entire apparatus. Accordingly, how to properly lock the components without sacrificing the strength of the apparatus structure is one of the issues to be resolved at present.

### SUMMARY OF THE INVENTION

The invention is directed to a display in which modules can be assembled without forming a hole on a frame.

The invention is further directed to a touch display that has favorable mechanical strength.

The invention is further directed to a method of manufacturing a frame. By applying the method, the frame having a locking structure can be formed without forming a hole on the frame.

In an embodiment of the invention, a display that includes a first frame, a second frame, and a display panel is provided. The first frame includes a bottom surface, a sidewall, and a strengthened structure. The sidewall connects the bottom surface to define an accommodation space. The strengthened structure connects a terminal of the sidewall away from the bottom surface. Besides, the strengthened structure is located at a side of the sidewall that faces the accommodation space, and the strengthened structure is substantially parallel to the sidewall. The strengthened structure has a contact surface, and the contact surface faces the bottom surface and is substantially parallel to the bottom surface. The second frame is configured in the accommodation space and has a locking portion. The locking portion has a locking surface that leans against the contact surface of the strengthened structure. The display panel is accommodated in the second frame.

In an embodiment of the invention, a touch display that includes a first frame, a second frame, a display panel, and a touch panel is provided. The first frame includes a bottom surface, a sidewall, and a strengthened structure. The sidewall connects the bottom surface to define an accommodation space. The strengthened structure connects a terminal of the sidewall away from the bottom surface. Besides, the strengthened structure is located at a side of the sidewall that faces the accommodation space, and the strengthened structure is substantially parallel to the sidewall. The strengthened structure has a contact surface. The contact surface faces the bottom surface and is substantially parallel to the bottom surface. The second frame is configured in the accommodation space and has a locking portion that has a locking surface. The locking surface leans against the contact surface of the strengthened structure. The display panel is accommodated in the second frame. The touch panel is configured on the second frame and surrounded by the strengthened structure.

In an embodiment of the invention, a method of manufacturing a frame is provided. In the method, a flexible board that includes a bottom portion, a sidewall portion, and a strengthened portion is provided. The sidewall portion connects a side of the bottom portion. The strengthened portion connects a side of the sidewall portion away from the bottom portion. The strengthened portion is bent and flattened, such that the strengthened portion is parallel to the sidewall portion. The sidewall portion is bent, such that an included angle is formed between the sidewall portion and the bottom portion to define an accommodation space. The strengthened portion has a contact surface, and the contact surface faces the bottom portion and is substantially parallel to the bottom portion.

Based on the above, according to the invention, a strengthened structure is bent at a side of the sidewall of the frame, and the locking structure is defined by the height design of the strengthened structure. Thereby, by locking another frame to the strengthened structure, two frames can be assembled together. It is not necessary to form holes on the frame in this invention, such that the mechanical strength of the frame is not negatively affected. In addition, the strengthened structure is conductive to strengthening the sidewall of the frame, such that the display and the touch display can have favorable mechanical strength. Moreover, the strengthened structure and the sidewall substantially contact each other, and the small side width does not pose a negative impact on the area of the display region in the invention.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic partial view illustrating a display according to an embodiment of the invention.

FIG. 2 and FIG. 3 are schematic partial views respectively illustrating the first frame and the second frame depicted in FIG. 1.

FIG. 4 is a schematic partial view illustrating a touch display module according to an embodiment of the invention.

FIG. 5 and FIG. 6 are schematic partial views respectively illustrating the first frame and the second frame depicted in FIG. 4.

FIG. 7A to FIG. 7E illustrate a method of manufacturing a frame according to an embodiment of the invention.

FIG. 8 is a schematic view illustrating a frame according to another embodiment of the invention.

FIG. 9 is a cross-section view of the touch panel according to an embodiment of the invention.

FIG. 10A is a bottom view of the touch sensor layer 2513 shown in FIG. 9 according to an embodiment of the present invention.

FIG. 10B is a cross-section view of the touch panel taken along line A-A′ of FIG. 10A.

FIG. 11 through FIG. 13 are schematic diagrams respectively illustrating the touch panel according to three different variant embodiments of FIG. 10A and FIG. 10B.

FIG. 14A is a bottom view of another type of the touch sensor layer 2513 shown in FIG. 9 according to another embodiment of the present invention.

FIG. 14B is a cross-section view of the touch panel taken along line B-B′ of FIG. 14A.

FIG. 15 is a schematic diagram illustrating the touch panel according to a variant embodiment of FIG. 14A and FIG. 14B.

FIG. 16 and FIG. 17 are schematic diagrams illustrating the touch panel according to two variant embodiments of the invention.

### DESCRIPTION OF EMBODIMENTS

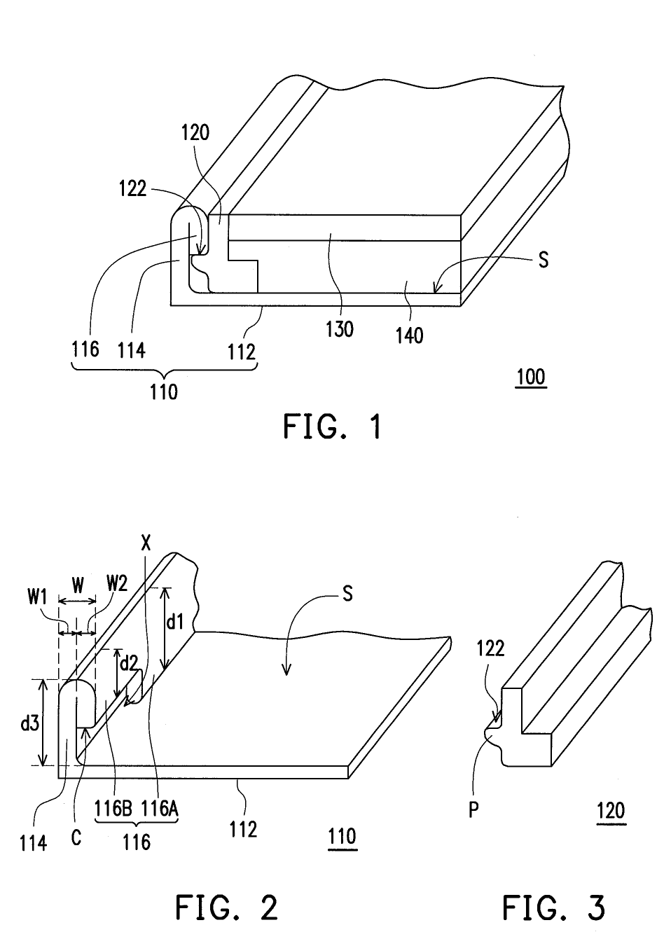

FIG. 1 is a schematic partial view illustrating a display according to an embodiment of the invention. With reference to FIG. 1, the display 100 includes a first frame 110, a second frame 120, a display panel 130, and a backlight module 140. The first frame 110 includes a bottom surface 112, a sidewall 114, and a strengthened structure 116. The sidewall 114 connects the bottom surface 112 to define an accommodation space S. The strengthened structure 116 connects a terminal of the sidewall 114 away from the bottom surface 112. Besides, the strengthened structure 116 is located at a side of the sidewall 114 that faces the accommodation space S, and the strengthened structure 116 is substantially parallel to the sidewall 114. The second frame 120 is configured in the accommodation space S and has a locking surface 122 that leans against the strengthened structure 116. The display panel 130 and the backlight module 140 are accommodated in the second frame 120, and the backlight module 140 is located at a side of the display panel 130 close to the bottom surface 112.

In this embodiment, the display panel 130 is an LCD panel, for instance, and therefore the display 100 requires the backlight module 140 that acts as the display light source. In other embodiments, given the display panel 130 is a self-illuminating display panel (e.g., an organic electroluminescent display panel) or a reflective display panel (e.g., an electrophoretic display panel or an electrowetting display panel), the backlight module 140 in the display 100 can be omitted. That is to say, this embodiment exemplifies the invention and should not be construed as a limitation to the invention. It should be mentioned that the correlation of each component is schematically illustrated in FIG. 1, while the detailed structural design of each component is not limited to that depicted in FIG. 1. For instance, the backlight module 140 can include a light source, a light guide plate, and so on, and these elements are not completely shown in FIG. 1.

According to this embodiment, the strengthened structure 116 of the first frame 110 corresponds to the locking surface 122 of the second frame 120. Hence, the first frame 110 and the second frame 120 can be locked together without forming any hole on the first frame 110. Thereby, the mechanical strength of the first frame 110 is not reduced because of the configuration of the hole. To be more specific, the strengthened structure 116 and the sidewall 114 of the first frame 110 are parallel to each other and are in contact with each other in this embodiment, so as to enhance the strength of the sidewall 114. As a whole, the strength of the first frame 110 can be significantly improved by the strengthened structure 116.

FIG. 2 and FIG. 3 are schematic partial views respectively illustrating the first frame 110 and the second frame 120 depicted in FIG. 1. With reference to FIG. 1 to FIG. 3, in this embodiment, a material of the first frame 110 is metal, for instance. The strengthened structure 116 includes a first strengthened portion 116A and a second strengthened portion 116B. The first strengthened portion 116A has a height d1 perpendicular to the bottom surface 112, and the second strengthened portion 116B has a height d2 perpendicular to the bottom surface 112. The height d1 is greater than the height d2. The second strengthened portion 116B partially exposes the sidewall 114. Besides, the second strengthened portion 116B has a contact surface C. The contact surface C substantially faces the bottom surface 112 and is parallel to the bottom surface 112. The contact surface C, the sidewall 114, and the bottom surface 112 together form a locking space X. Particularly, the strengthened structure 116 has a thickness W2, and the second strengthened portion 116B of the strengthened structure 116 does not completely cover the sidewall 114. Therefore, the second strengthened portion 116B constitutes a locking design (i.e., the locking space X) on the first frame 110.

The second frame 120 is made of a polymer material, for instance. Here, the second frame 120 includes a locking portion P. As indicated in FIG. 1, when the first frame 110 and the second frame 120 are assembled together, the locking portion P enters the locking space X until the locking portion P leans against the sidewall 114 of the first frame 110. Here, the locking portion P substantially has the locking surface 122 that can be locked to the contact surface C of the second strengthened portion 116B. That is to say, the locking surface 122 leans against the contact surface C of the second strengthened portion 116B in this embodiment. By locking the locking portion P and the second strengthened portion 116B, the first frame 110 and the second frame 120 can be fixed together.

In addition, the sidewall 114 and the strengthened structure 116 in the first frame 110 are substantially in contact with each other and parallel to each other. Namely, the sidewall 114 and the strengthened structure 116 closely lean against each other. As such, the strengthened structure 116 is conducive to improvement of the mechanical strength of the first frame 110. In addition, since the strengthened structure 116 and the sidewall 114 lean against each other, the volume of the display 100 can be reduced. In particular, the width of the border of the display 100 can be reduced, i.e., the visible region of the display 100 is increased.

In this embodiment, the side width W of the first frame 110 is substantially equal to the thickness W1 of the sidewall 114 and the thickness W2 of the strengthened structure 116 in total. Specifically, the first frame 110 can be formed by punching the same metal board, and therefore the sidewall 114 and the strengthened structure 116 have substantially the same thickness. Hence, the side width W of the first frame 110 can be substantially equal to twice the thickness of the metal board. Under said design, the increased width of the border of the display 100 is approximately equal to the thickness of the metal board, such that the display 100 is still applicable to products with slim border design.

In detail, the first frame 110 is made by bending the metal board. The bent portions, e.g., the connecting portion between the bottom surface 112 and the sidewall 114 and the connecting portion between the strengthened structure 116 and the sidewall 114 are round corners, for instance. In addition, according to this embodiment, the first strengthened portion 116A of the strengthened structure 116 can be selectively in contact with or not in contact with the bottom surface 112. Therefore, the height d3 of the sidewall 114 can be slightly greater than the height d1 of the first strengthened portion 116A. However, in other embodiments of the invention, the height d1 of the first strengthened portion 116A can be substantially equal to the height d3 of the sidewall 114, such that the first strengthened portion 116A can lean against the bottom surface 112.

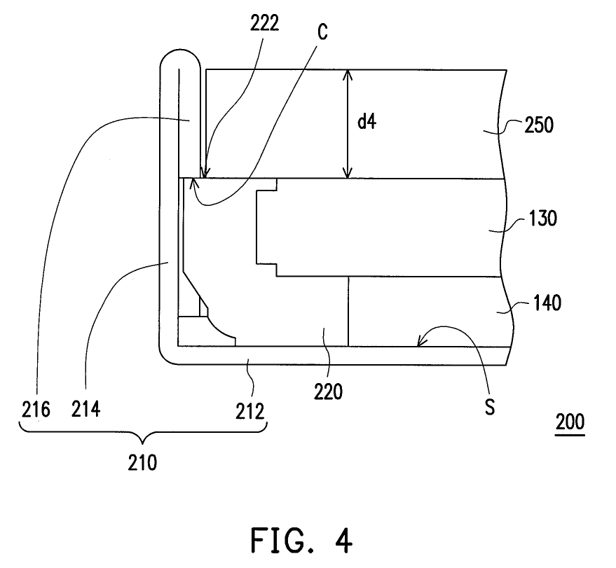

FIG. 4 is a schematic partial view illustrating a touch display module according to an embodiment of the invention. With reference to FIG. 4, the touch display module 200 includes a first frame 210, a second frame 220, a display panel 130, a backlight module 140, and a touch panel 250. The first frame 210 includes a bottom surface 212, a sidewall 214, and a strengthened structure 216. The sidewall 214 connects the bottom surface 212 to define an accommodation space S. The strengthened structure 216 connects a terminal of the sidewall 214 away from the bottom surface 212. Besides, the strengthened structure 216 is located at a side of the sidewall 214 that faces the accommodation space S, and the strengthened structure 216 is substantially parallel to the sidewall 214. The second frame 220 is located in the accommodation space S. The locking portion (not shown) of the second frame 220 is the sidewall of the second frame 220, for instance, and the locking portion (not shown) has a locking surface 222 that leans against the contact surface C of the strengthened structure 216. The display panel 130 and the backlight module 140 are accommodated in the second frame 220, and the backlight module 140 is located at a side of the display panel 130 close to the bottom surface 212. The touch panel 250 is configured on the second frame 220 and located at a side of the display panel 130 away from the backlight module 140. Besides, the touch panel 250 is surrounded by the strengthened structure 216. In an embodiment of the invention, the touch panel 250 can include a substrate and a sensing structure. The sensing structure is configured at one side of the substrate, and the other side of the substrate can be touched by users. Here, the sensing structure can be a layer of sensing electrodes or a plurality of sensing series.

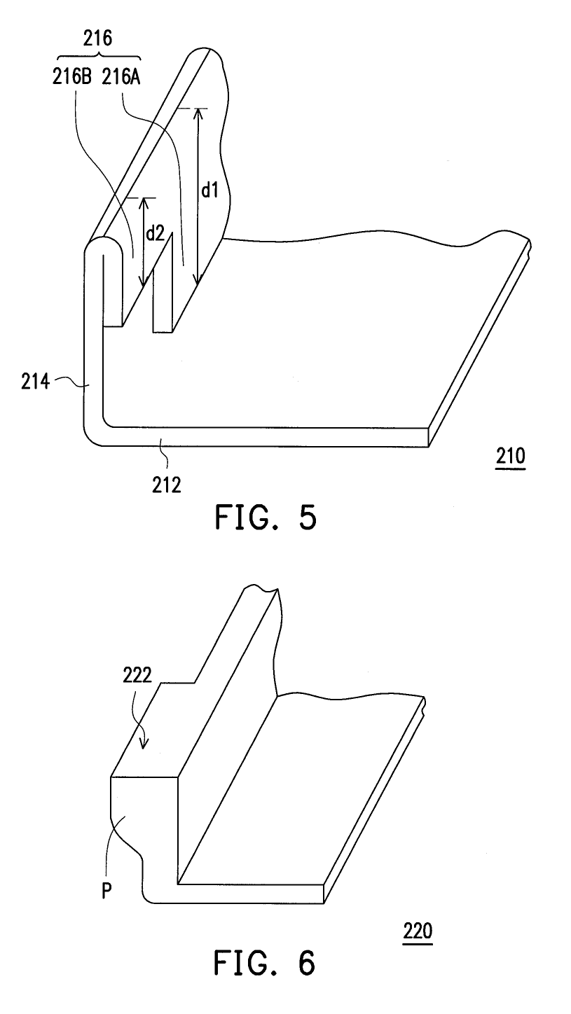

FIG. 5 and FIG. 6 are schematic partial views respectively illustrating the first frame and the second frame depicted in FIG. 4. With reference to FIG. 4 to FIG. 6, in this embodiment, the strengthened structure 216 of the first frame 210 includes a first strengthened portion 216A and a second strengthened portion 216B. Here, the height dl of the first strengthened portion 216A is greater than the height d2 of the second strengthened portion 216B. Similar to the previous embodiment, in this embodiment, the strengthened structure 216 closely leans against the sidewall 214, so as to enhance the mechanical strength and reduce the width of the border. It should be mentioned that the height d2 of the second strengthened portion 216B of the strengthened structure 216 is substantially equal to or greater than the height d4 of the touch panel 250, so as to protect the touch panel 250.

Additionally, in this embodiment, the second frame 220 includes a protruding locking portion P, and the locking portion P protrudes from the central part of the accommodation space S defined by the first frame 210 to the sidewall 214 of the first frame 210. The protruding locking portion P has a locking surface 222 that can be locked to the terminal of the second strengthened portion 216B. Particularly, the locking surface 222 and the top surface of the second frame 220 that holds the touch panel 250 are coplanar in this embodiment. However, the invention is not limited thereto. In other embodiments, the locking portion P depicted in FIG. 3 can be applied to the touch display module 200 of this embodiment. Namely, the locking surface 222 and the top surface of the second frame 220 that holds the touch panel 250 can be difference planes.

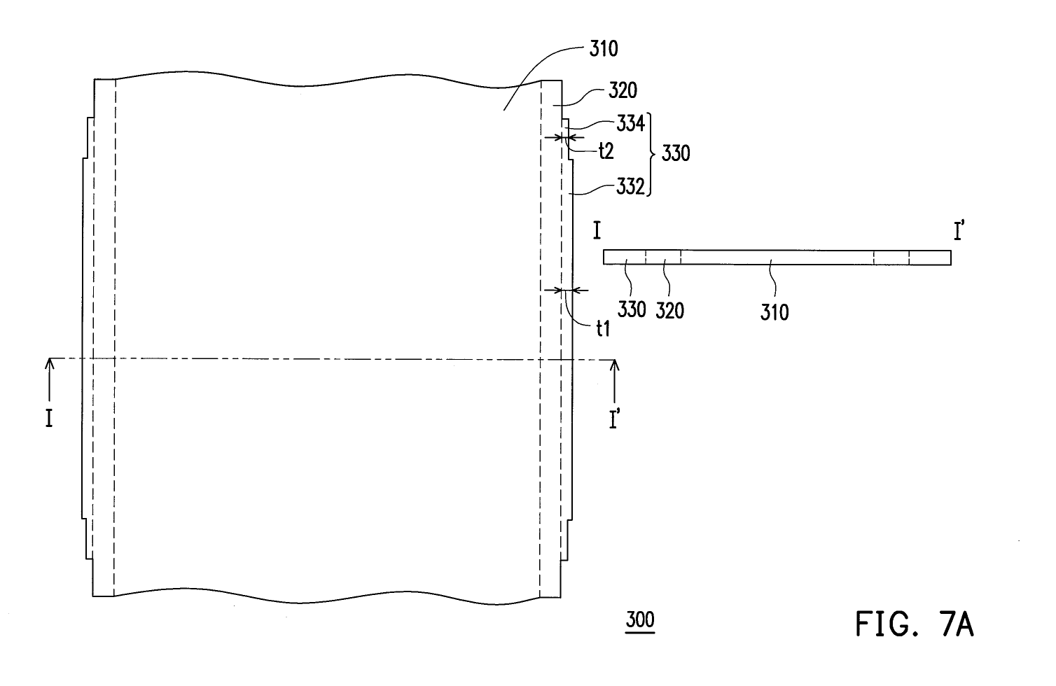

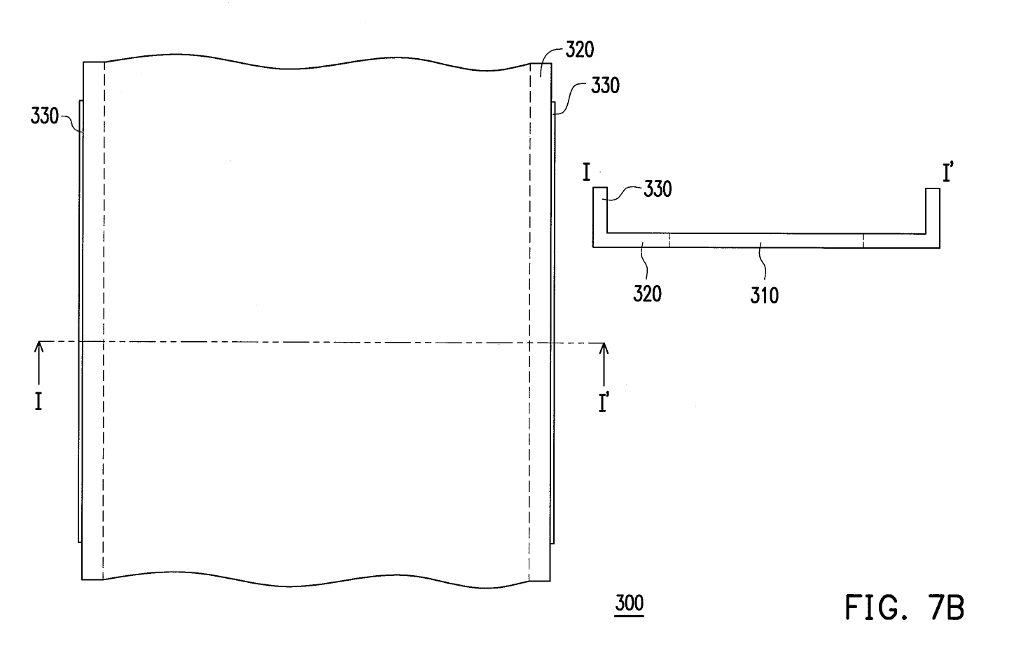

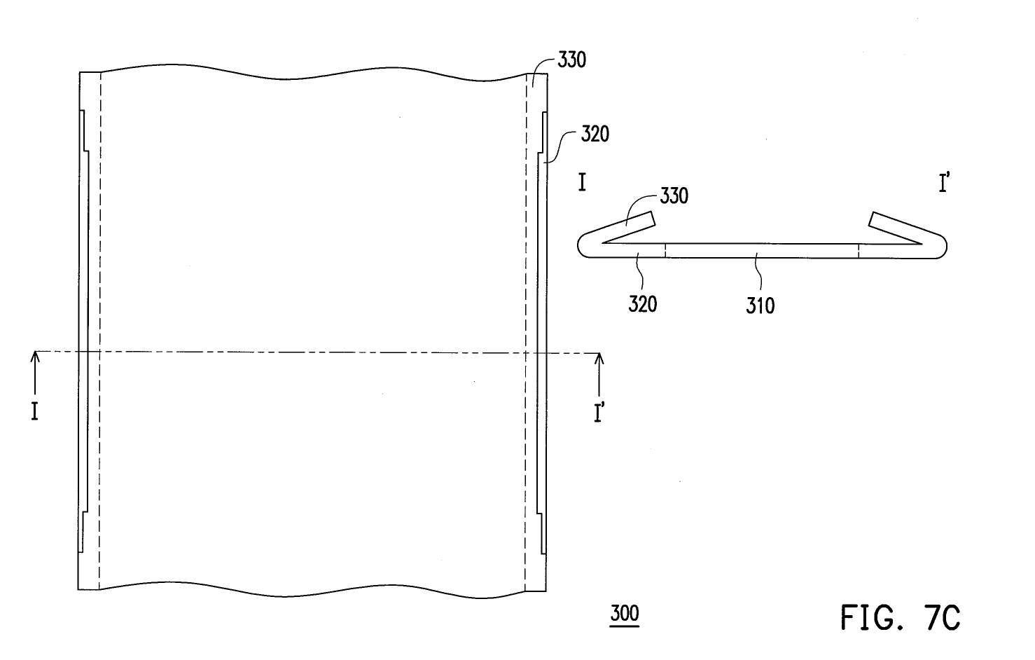

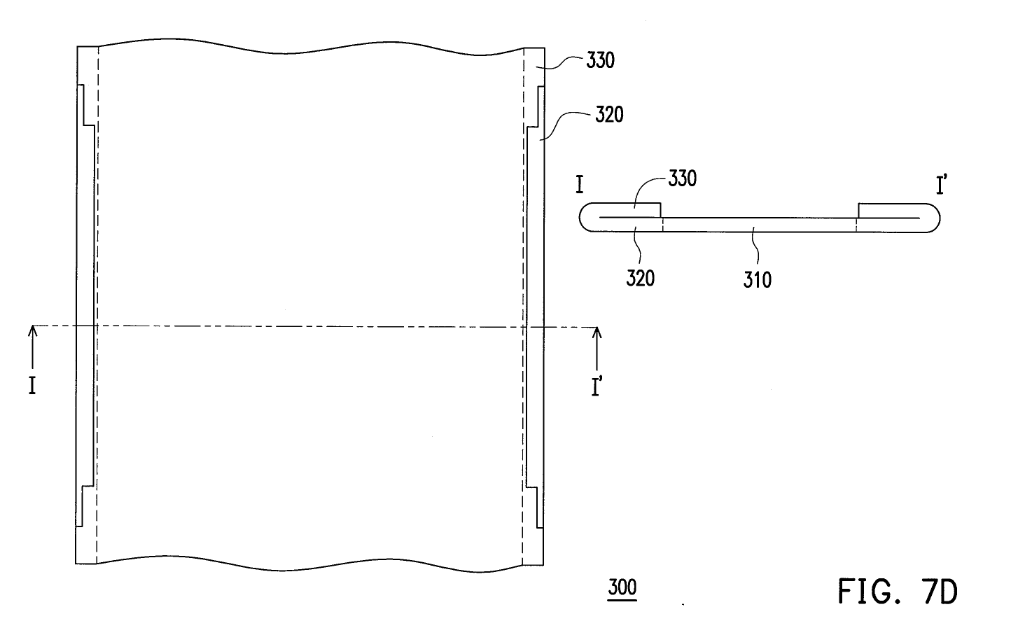

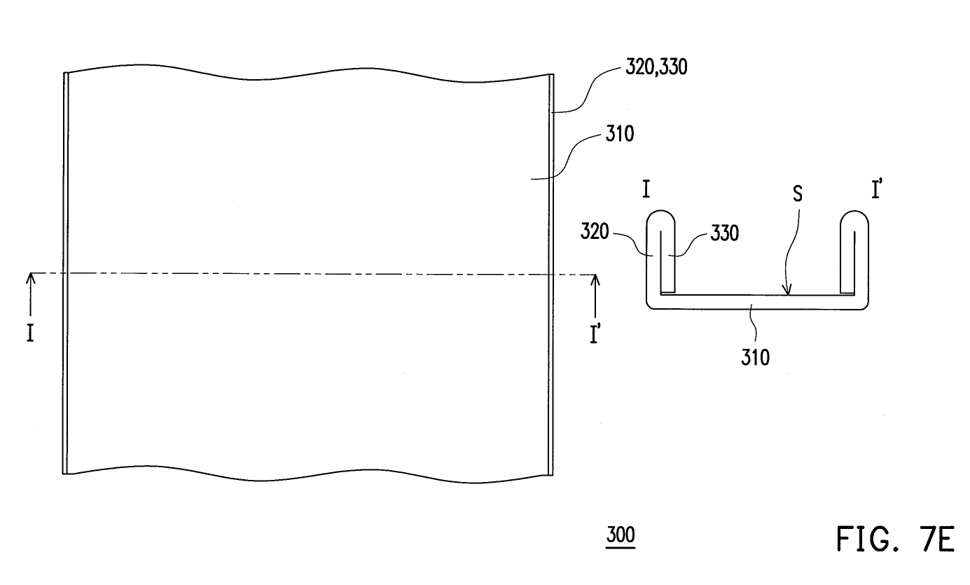

In detail, the first frame 110 and the first frame 210 described in the previous embodiments are made by bending the same flexible metal board. FIG. 7A to FIG. 7E illustrate a method of manufacturing a frame according to an embodiment of the invention. As indicated in FIG. 7A, a flexible board 300 is provided, and the flexible board 300 can be made of metal, alloy, or any other flexible material. The flexible board 300 includes a bottom portion 310, a sidewall portion 320, and a strengthened portion 330. The sidewall portion 320 connects a side of the bottom portion 310. The strengthened portion 330 connects a side of the sidewall portion 320 away from the bottom portion 310. Here, the strengthened portion 330 includes a first strengthened portion 332 and a second strengthened portion 334, and a width t1 of the first strengthened portion 332 is greater than a width t2 of the second strengthened portion 334.

With reference to FIG. 7B, the strengthened portion 330 is bent, such that an included angle (e.g., a right angle) is between the strengthened portion 330 and the bottom portion 310. With reference to FIG. 7C, a side punching process is performed, such that the bent strengthened portion 330 approaches the sidewall portion 320. With reference to FIG. 7D, the strengthened portion 330 is flattened, such that the strengthened portion 330 is substantially parallel to the sidewall portion 320. Here, the strengthened portion 330 and the sidewall portion 320 closely lean against each other, for instance. As indicated in FIG. 7E, the sidewall portion 320 is bent, such that an included angle (e.g., a right angle) is between the sidewall portion 320 and the bottom portion 310 to define an accommodation space S. As such, the first frame 110 and the first frame 210 described in the previous embodiments can be formed.

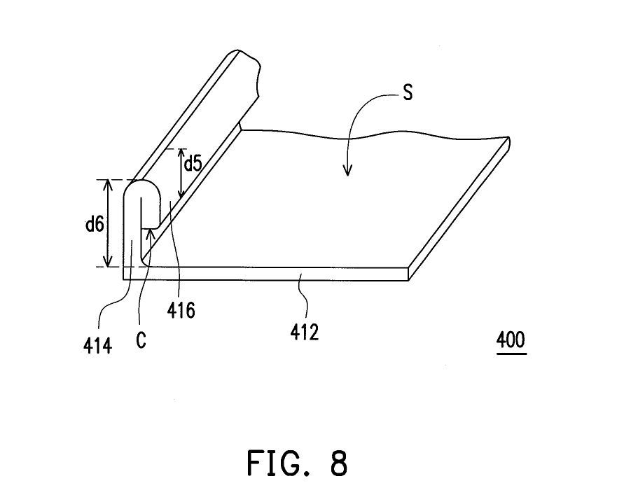

Note that both the strengthened structure 116 of the first frame 110 and the strengthened structure 216 of the first frame 210 described in the previous embodiments contain different portions at least having two heights. Nonetheless, the invention should not be construed as limited to the embodiments set forth herein. For instance, please refer to FIG. 8, which is a schematic view illustrating a frame according to another embodiment of the invention. The frame 400 shown in FIG. 8 includes a bottom surface 412, a sidewall 414, and a strengthened structure 416. The sidewall 414 connects the bottom surface 412 to define an accommodation space S. The strengthened structure 416 connects a terminal of the sidewall 414 away from the bottom surface 412. Besides, the strengthened structure 416 is located at a side of the sidewall 414 that faces the accommodation space S, and the strengthened structure 416 is substantially parallel to and in contact with the sidewall 414. The strengthened structure 416 has a contact surface C. The contact surface C faces the bottom surface 412 and is substantially parallel to the bottom surface 412. It should be mentioned that the height d5 of the strengthened structure 416 has a fixed value and is less than the height d6 of the sidewall 414.

According to this embodiment, the strengthened structure 416 not only can be conducive to improvement of the mechanical properties of the frame 400 but also can perform a locking function, such that the frame 400 can be assembled to other frames or other components. Specifically, the frame 400 can be locked to the second frame 120 depicted in FIG. 3 or the second frame 220 depicted in FIG. 6. In the second frame 120 depicted in FIG. 3 or the second frame 220 depicted in FIG. 6, the locking portion P can have a stripe-shaped design, and the length of the locking portion P can be substantially equal to the extension length of the strengthened structure 416.

It is noted that the touch panel 250 as depicted in FIG. 4 can be any type of the touch panel, for example, such as the capacitive type touch panel, the resistive type touch panel, the optical type touch panel, or the like. Herein, several examples are provided for further clearly pointing out the design of the touch panel of the present invention. However, the examples illustrated in the following are not intent to be construed as the limitation of the present invention.

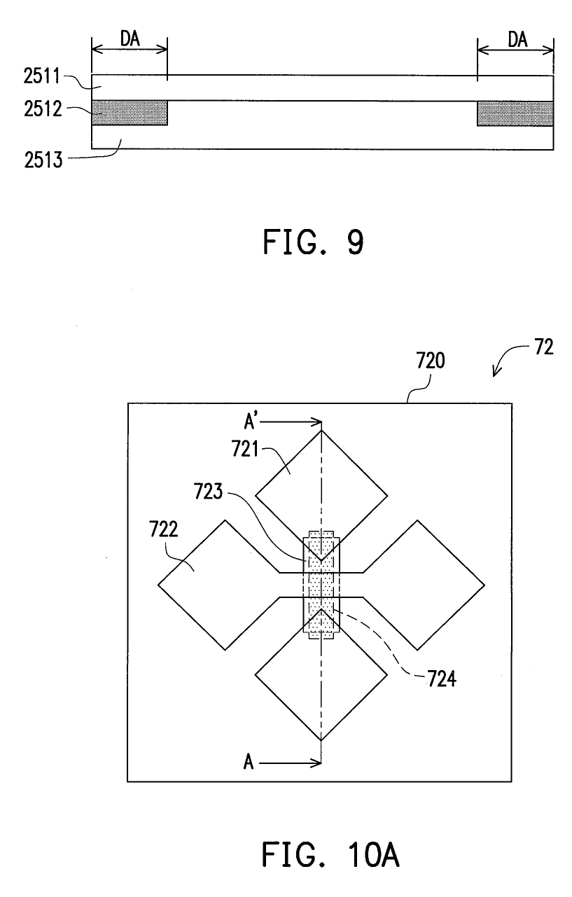

FIG. 9 is a cross-section view of the touch panel according to an embodiment of the invention. Referring to FIG. 9, the touch panel 250 of the present invention includes a transparent substrate 2511, a patterned decoration layer 2512, and a touch sensor layer 2513. The transparent substrate 2511 can be selected from a cover lens, a glass substrate, or a plastic substrate, but not limited thereto. The patterned decoration layer 2512 is formed on the transparent substrate 2511, preferably formed on a non-transparent area DA of the transparent substrate 2511. The touch sensor layer 2513 is formed on the transparent substrate 2511. It is noted that no matter whether the touch sensor layer 2513 is designed, the patterned decoration layer 2512 can be configured surrounding the touch sensor layer 2513 in the touch panel 250.

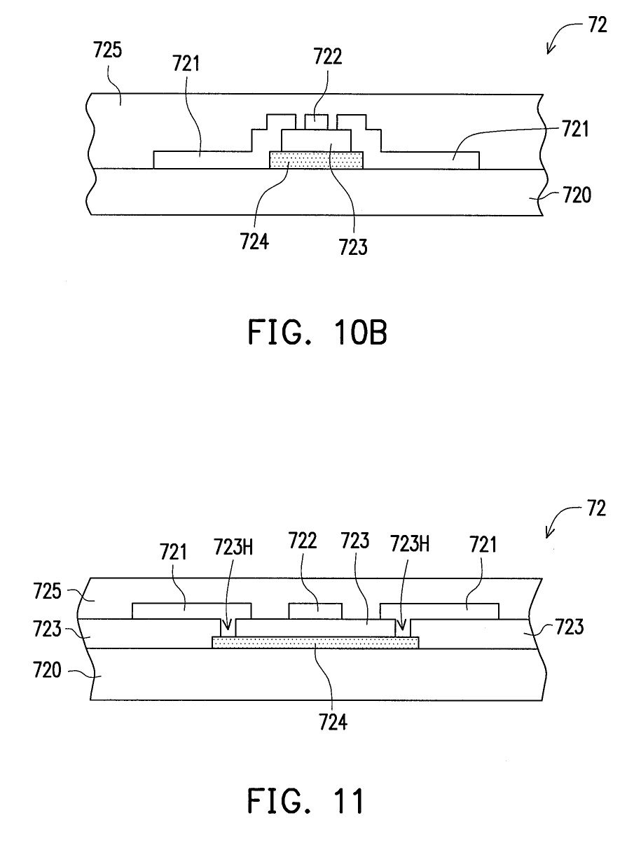

FIG. 10A is a bottom view of the touch sensor layer 2513 shown in FIG. 9 according to an embodiment of the present invention, and FIG. 10B is a cross-section view of the touch panel taken along line A-A′ of FIG. 10A. As shown in FIG. 10A and FIG. 10B, in this embodiment, the touch panel can be, for example, a capacitive touch panel 72, which includes a substrate 720, a bridge line 724, an insulating layer 723, a plurality of first electrodes 721 and a plurality of second electrodes 722. The bridge line 724 is disposed on the substrate 720; the insulating layer 723 covers the bridge line 724, and exposes two terminals of the bridge line 724 and part of the substrate 720; the first electrodes 721 are disposed on the substrate 720, and electrically connected to the exposed two terminals of the bridge line 724; the second electrodes 722 are disposed on the insulating layer 723, and the two adjacent two second electrodes 722 can be electrically connected together directly, but not limited thereto. A passivation layer 725 may be selectively formed on the first electrodes 721, the second electrodes 722, the insulating layer 723 and the bridge line 724. In this embodiment, the bridge line 724 may be a single-layered bridge line e.g. a metal bridge line or a transparent conducting bridge line such as an indium tin oxide (ITO) bridge line, or a multi-layered bridge line such as a stacking structure formed by metal and transparent conducting material. The first electrodes 721 and the second electrodes 722 may be formed by the same transparent conducting material, and patterned by the same patterning process.

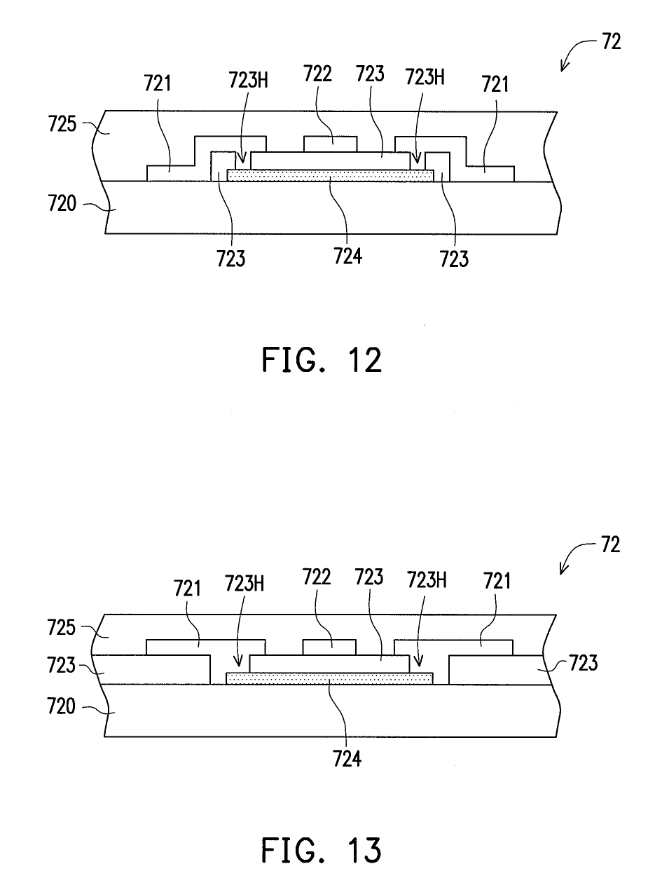

Please refer to FIG. 11 through FIG. 13. FIG. 11 through FIG. 13 are schematic diagrams respectively illustrating the touch panel according to three different variant embodiments of FIG. 10A and FIG. 10B. In these three variant embodiments, the first electrode 721 is electrically connected to the bridge line 724 through the contact hole 723H of the insulating layer 723. The contact hole 723H may only expose the bridge line 724 (as shown in FIG. 11 and FIG. 12), or the contact hole 723H may expose the bridge line 724 and part of the substrate 720 (as shown in FIG. 13). In addition, the insulating layer 723 may cover the substrate 720 thoroughly (as shown in FIG. 11), or may only partially cover the substrate 720 (as shown in FIG. 12).

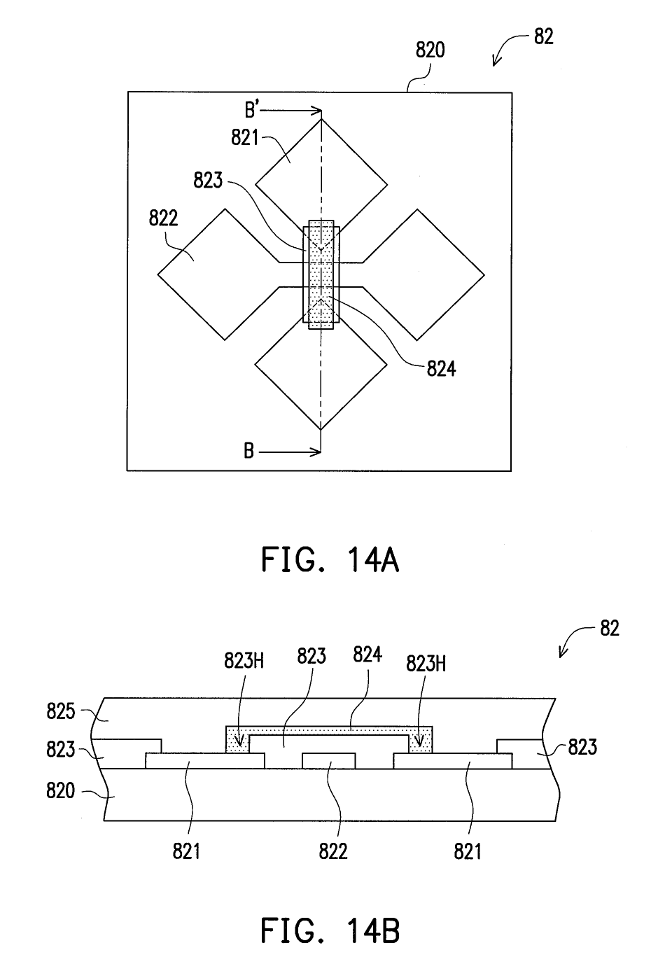

FIG. 14A is a bottom view of another type of the touch sensor layer 2513 shown in FIG. 9 according to another embodiment of the present invention, and FIG. 14B is a cross-section view of the touch panel taken along line B-B′ of FIG. 14A. As shown in FIG. 14A and FIG. 14B, in this embodiment, the touch panel can be, for example, a capacitive touch device 82, which includes a substrate 820, a plurality of first electrodes 821, a plurality of second electrodes 822, an insulating layer 823 and a bridge line 824. The first electrodes 821 and the second electrodes 822 may be formed by the same transparent conducting material and disposed on the substrate 820. The insulating layer 823 covers the substrate 820, the first electrodes 821 and the second electrodes 822, and partially exposes the first electrodes 821. The bridge line 824 is disposed on the insulating layer 823, and electrically connected to the exposed adjacent first electrodes 821, and the adjacent second electrodes 822 may be electrically connected directly, but not limited thereto. A passivation layer 825 may be selectively formed on the insulating layer 823 and the bridge line 824.

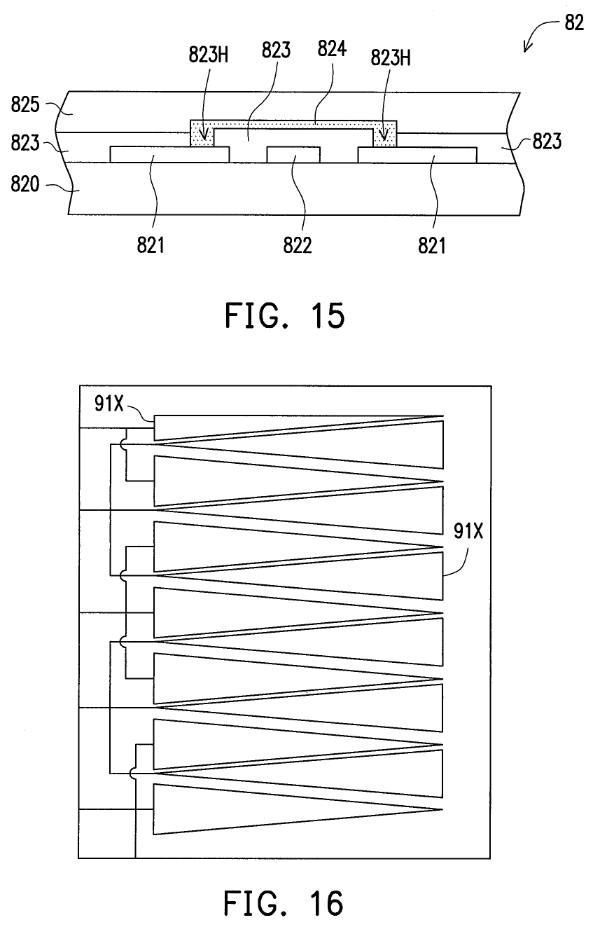

FIG. 15 is a schematic diagram illustrating the touch panel according to a variant embodiment of FIG. 14A and FIG. 14B. As shown in FIG. 15, the bridge line 824 is entirely filled into the contact hole 823H of the insulating layer 823 to electrically connect the adjacent first electrodes 821.

Specifically, the touch panel of the present invention is not limited to the above embodiments. For example, the first electrodes 821 and the second electrodes 822 may be formed separately by different conducting materials. In this case, the first electrodes 821 the may be directly connected without requiring the bridge line 824. In addition, the above mentioned designs of the first electrodes 721 and 821 and the second electrodes 722 and 822 are exemplarily served as the plurality of the sensing electrodes in the touch panels, but the invention is not limited thereto. Other designs of the electrodes such as a plurality of electrodes in a single layer can be served as the sensing electrodes of the touch panel.

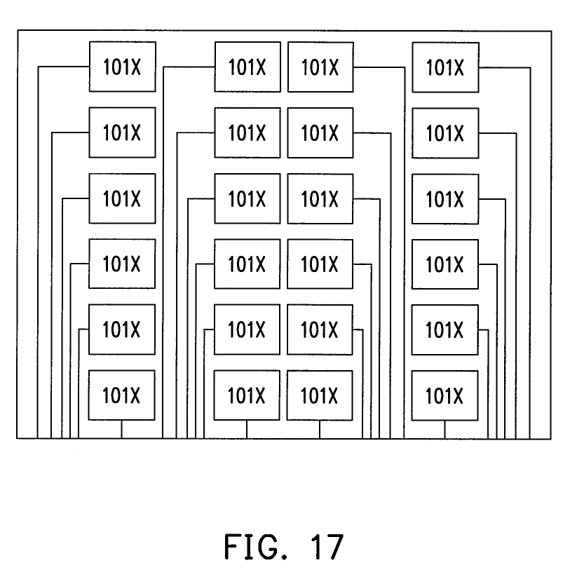

For example, the electrodes 91X having the triangle shape depicted in FIG. 16 can be served as the sensing electrodes of the touch panel. Alternately, the electrodes 101X having the rectangle shape as depicted in FIG. 17 can be selectively served as the sensing electrodes of the touch panel. The electrodes 91X and the electrodes 101X illustrated in FIG. 16 and FIG. 17 can be formed by a single conducting layer, or multiple different conducting layers.

In light of the foregoing, the flexible board of this invention is properly cut, shaped, and bent, so as to form the frame, and no punching process for forming holes is required. Hence, the mechanical strength of the frame is not reduced by the holes. Moreover, the sidewall of the frame is bent for enhancing the structure and further improving the mechanical strength of the frame. Thus, the display and the touch display described in the invention have favorable mechanical strength. Further, the two layers of the frame formed by performing a bending process can closely lean against each other according to the invention, and the width of the borders of the display and the touch display is not significantly increased. As a result, the display and the touch display described in the invention not only have favorable mechanical strength but also have slim boarder.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A display comprising:
a first frame comprising:
a bottom surface;
a sidewall connecting the bottom surface to define an accommodation space;
a strengthened structure connecting a terminal of the sidewall away from the bottom surface, the strengthened structure being located at a side of the sidewall facing the accommodation space, the strengthened structure being substantially parallel to and in contact with the sidewall, wherein the strengthened structure has a contact surface, and the contact surface faces the bottom surface and is substantially parallel to the bottom surface;
a second frame configured in the accommodation space and having a locking portion, the locking portion having a locking surface, the locking surface leaning against the contact surface of the strengthened structure; and
a display panel accommodated in the second frame.

2. The display as claimed in claim 1, wherein the strengthened structure comprises a first strengthened portion and a second strengthened portion, a height of the first strengthened portion is greater than a height of the second strengthened portion, and the second strengthened portion has the contact surface.

3. The display as claimed in claim 1, wherein the contact surface, the sidewall, and the bottom surface together define a locking space, and the locking portion is located in the locking space.

4. The display as claimed in claim 1, wherein a side width of the first frame is substantially equal to a total thickness of the sidewall and the strengthened structure.

5. The display as claimed in claim 1, wherein a thickness of the sidewall and a thickness of the strengthened structure are substantially the same.

6. The display as claimed in claim 2, wherein a height of the sidewall is substantially greater than the height of the first strengthened portion.

7. The display as claimed in claim 1, further comprising a backlight module located in the second frame and at a side of the display panel close to the bottom surface of the first frame.

8. A touch display comprising:
a first frame comprising:
a bottom surface;
a sidewall connecting the bottom surface to define an accommodation space;
a strengthened structure connecting a terminal of the sidewall away from the bottom surface, the strengthened structure being located at a side of the sidewall facing the accommodation space, the strengthened structure being substantially parallel to and in contact with the sidewall, wherein the strengthened structure has a contact surface, and the contact surface faces the bottom surface and is substantially parallel to the bottom surface;
a second frame configured in the accommodation space and having a locking portion, the locking portion having a locking surface, the locking surface leaning against the contact surface of the strengthened structure;
a display panel accommodated in the second frame; and
a touch panel configured on the second frame and surrounded by the strengthened structure.

9. The touch display as claimed in claim 8, wherein the contact surface, the sidewall, and the bottom surface together define a locking space, and the locking portion is located in the locking space.

10. The touch display as claimed in claim 9, wherein the locking surface and a top surface of the second frame holding the touch panel are coplanar.

11. A method of manufacturing a frame, comprising:
providing a flexible board, the flexible board comprising a bottom portion, a sidewall portion, and a strengthened portion, the sidewall portion connecting a side of the bottom portion, the strengthened portion connecting a side of the sidewall portion away from the bottom portion;
bending and flattening the strengthened portion, such that the strengthened portion is parallel to the sidewall portion;
bending the sidewall portion, such that an included angle is between the sidewall portion and the bottom portion to define an accommodation space, wherein the strengthened portion has a contact surface, and the contact surface faces the bottom portion and is substantially parallel to the bottom portion.
